(19) United States
(12) Patent Application Publication
(10) Pub. No.: US 2017/0175265 A1
(43) Pub. Date: Jun. 22, 2017

(54) FLAT SUSCEPTOR WITH GROOVES FOR MINIMIZING TEMPERATURE PROFILE ACROSS A SUBSTRATE

(71) Applicant: Applied Materials, Inc., Santa Clara, CA (US)

(72) Inventors: Kartik SHAH, Sunnyvale, CA (US); Schubert S. CHU, San Francisco, CA (US); Nyi O. MYO, San Jose, CA (US); Karthik RAMANATHAN, Bangalore (IN); Richard O. COLLINS, Santa Clara, CA (US); Zhepeng CONG, Vancouver, WA (US); Nitin PATHAK, Bangalore (IN)

(21) Appl. No.: 14/974,541

(22) Filed: Dec. 18, 2015

(51) Int. Cl. C23C 16/458; H01L 21/687

(52) U.S. Cl. CPC C23C 16/4583; H01L 21/68714

(57) ABSTRACT

In one embodiment, a susceptor is provided and includes a first major surface opposing a second major surface, and a plurality of contact structures disposed on the first major surface, each of the contact structures being at least partially surrounded by one or more of a plurality of radially oriented grooves and an annular groove, wherein each of the plurality of contact structures includes a substrate contact surface, each of the substrate contact surfaces is between two parallel planes separated by a distance of 0.1 millimeters, and the substrate contact surfaces define a substrate receiving surface.

### BACKGROUND

Field

Embodiments of the disclosure generally relate to a susceptor for supporting a substrate in a processing chamber. More specifically, a susceptor having a flat substrate receiving surface with a groove pattern formed thereon that may be utilized in a deposition or etch chamber for semiconductor fabrication processes.

Description of the Related Art

In the manufacture of electronic devices on a substrate, substrates, such as a semiconductor substrate, are subjected to many thermal processes. The thermal processes are typically performed in a dedicated processing chamber where material is deposited or removed. Such processes include epitaxial deposition, chemical vapor deposition (CVD), plasma enhanced chemical vapor deposition (PECVD), etching, annealing, and the like.

A substrate is typically supported on a susceptor in the processing chamber and, in some deposition processes; a bottom surface of the susceptor is heated to raise the temperature of the substrate. A conventional susceptor has a substrate receiving surface that is typically not planar or flat such that a large area of the substrate may not contact the substrate receiving surface resulting in a gap therebetween. The gap and/or non-contact between the substrate and the susceptor results in a large temperature difference between the substrate and the bottom surface of the susceptor. Further, the temperature profile across the surface of the substrate is affected due to the gap and/or non-contact between the substrate and the susceptor. These temperature differences create challenges in controlling deposition on the substrate.

Thus, there is a need for an improved susceptor that minimizes temperature differences between the susceptor and a substrate supported thereon.

### SUMMARY

In one embodiment, a susceptor is provided and includes a first major surface opposing a second major surface, and a plurality of contact structures disposed on the first major surface, each of the contact structures being at least partially surrounded by one or more of a plurality of radially oriented grooves and an annular groove, wherein each of the plurality of contact structures includes a substrate contact surface, each of the substrate contact surfaces is between two parallel planes separated by a distance of 0.1 millimeters, and the substrate contact surfaces define a substrate receiving surface.

In another embodiment, a susceptor is provided and includes a first major surface opposing a second major surface, and a plurality of contact structures disposed on the first major surface, each of the contact structures being at least partially surrounded by one or more of a plurality of radially oriented grooves and an annular groove, wherein each of the plurality of contact structures include a substrate contact surface that defines a substrate receiving surface, and each of the substrate contact surfaces are disposed in a plane that is within about 0.1 millimeters across the substrate receiving surface.

In another embodiment, a susceptor is provided and includes a first major surface opposing a second major surface, and a plurality of contact structures disposed on the first major surface, each of the contact structures being at least partially surrounded by one or more of a plurality of radially oriented grooves and an annular groove, wherein each of the plurality of contact structures include a substrate contact surface that defines a substrate receiving surface, and each of the substrate contact surfaces are coplanar with each other, and the radially oriented grooves includes a first groove having a first radial length and a second groove having second radial length that is less than the remainder of the radially oriented grooves.

In another embodiment, a susceptor is provided and includes a first major surface opposing a second major surface, and a plurality of contact surfaces disposed on the first major surface, at least a portion of the contact surfaces being separated by, and alternating with, an annular groove, the annular grooves having a width and a depth along a radius of the of the first major surface, wherein each of the plurality of contact surfaces define a substrate receiving surface, and each of the substrate contact surfaces are coplanar with each other within about 0.1 millimeters across the substrate receiving surface.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a partial cross-sectional view of a processing chamber.

FIG. 2 is a perspective view of one embodiment of a susceptor that may be used in the processing chamber of FIG. 1.

FIG. 3 is a top plan view of the susceptor of FIG. 2 showing one embodiment of a groove pattern.

FIG. 4 is an enlarged view of a center area of the susceptor of FIG. 3.

FIGS. 5A and 5B are cross-sectional views of the susceptor along lines 5A-5A, and 5B-5B, of FIG. 3, respectively.

FIG. 6 is an enlarged partial cross-section of the susceptor of FIG. 5A.

FIG. 7 is an enlarged partial plan view of the susceptor of FIG. 3.

FIG. 8 is an enlarged partial cross-sectional view of the susceptor of FIG. 5A.

FIG. 9 is a schematic cross-sectional view of a portion of a susceptor that may be used as the susceptor.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the disclosure relate to an apparatus and method for a susceptor that supports a substrate during a process. The susceptor includes a major surface that is substantially planar or flat and includes a groove pattern that is configured to minimize temperature differences between the substrate and the susceptor, which may reduce a temperature delta across the surface of the substrate. The reduced temperature delta across the surface of the substrate improves deposition uniformity which may improve yield.

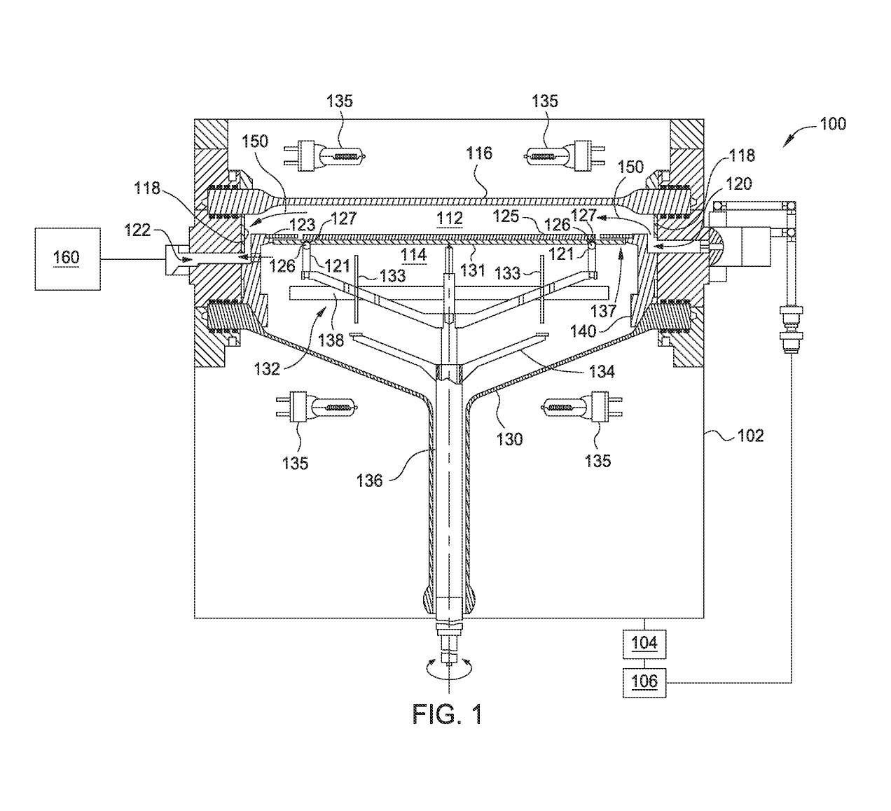

A variety of processing chambers may be modified to incorporate the embodiments described herein. In one embodiment, atmospheric chemical vapor deposition (CVD) chambers incorporate the embodiments described herein. One example of a CVD chamber is the epitaxial (EPI) CENTURA® system for atmospheric CVD systems, available from Applied Materials, Inc., of Santa Clara, Calif. The CENTURA® system is a fully automated semiconductor fabrication system, employing a single wafer, multi-chamber, modular design, which accommodates a wide variety of wafer sizes. In addition to the CVD chamber, the multiple chambers may include a pre-clean chamber, wafer orienter chamber, cool-down chamber, and independently operated loadlock chamber. The CVD chamber presented herein is shown in schematic in FIG. 1 is one embodiment and is not intended to be limiting of all possible embodiments. It is envisioned that other atmospheric or near atmospheric CVD chambers can be used in accordance with embodiments described herein, including chambers from other manufacturers.

FIG. 1 is a partial cross-sectional view of a processing chamber 100 according to one embodiment. The processing chamber 100 includes a chamber body 102, support systems 104, and a chamber controller 106. The chamber body 102 that includes an upper portion 112 and a lower portion 114. The upper portion 112 includes an area within the chamber body 102 between a ceiling 116 and an upper surface of a substrate 125. The lower portion 114 includes an area within the chamber body 102 between a dome 130 and a bottom of the substrate 125. Deposition processes generally occur on the upper surface of the substrate 125 within the upper portion 112.

An upper liner 118 is disposed within the upper portion 112 and is utilized to prevent undesired deposition onto chamber components. The upper liner 118 is positioned adjacent to a ring 123 within the upper portion 112. The processing chamber 100 includes a plurality of heat sources, such as lamps 135, which are adapted to provide thermal energy to components positioned within the processing chamber 100. For example, the lamps 135 may be adapted to provide thermal energy to the substrate 125 and the ring 123. The dome 130 and the ceiling 116 may be formed from an optically transparent material, such as quartz, to facilitate the passage of thermal radiation therethrough.

The chamber body 102 also includes an inlet 120 and an exhaust port 122 formed therein. The inlet 120 may be adapted to provide a process gas 150 into the upper portion 112 of the chamber body 102, while the exhaust port 122 may be adapted to exhaust the process gas 150 from the upper portion 112 into an exhaust system 160. In such a manner, the process gas 150 may flow parallel to the upper surface of the substrate 125. In one embodiment, thermal decomposition of the process gas 150 onto the substrate 125 forms an epitaxial layer on the substrate 125, facilitated by the lamps 135.

A substrate support assembly 132 is positioned in the lower portion 114 of the chamber body 102. The substrate support assembly 132 includes a susceptor 131 that is illustrated supporting the substrate 125 as well as the ring 123 in a processing position. The substrate support assembly 132 includes a plurality of support arms 121 and a plurality of lift pins 133. The lift pins 133 are vertically actuatable by support arms 134 and, in one embodiment, are adapted to contact the bottom of the susceptor 131 to lift the substrate 125 from a processing position (as shown) to a substrate transfer position. The substrate transfer position is a position where a robotic device (e.g., a robot arm or end effector) may be inserted through a sealable opening 138 and access the susceptor 131 (or other portions of the substrate support assembly 132). The components of the substrate support assembly 132 can be fabricated from carbon fiber, quartz, silicon carbide, graphite coated with silicon carbide or other suitable materials. The substrate support assembly 132 may include or is coupled to a shaft assembly 136 that allows movement of the support arms 121 separately from the movement of the lift pins 133. In one embodiment, the shaft assembly is adapted to rotate about a longitudinal axis thereof. In some embodiments, the substrate support assembly 132 includes a susceptor assembly 137, which includes the susceptor 131 and the ring 123 (or other supporting transfer mechanism(s) as described below), as well as portions of the support arms 134, the support arms 121 and/or the lift pins 133. In some embodiments, each support arm 121 includes a ball 126 configured to be received in a countersunk groove 127 formed in the susceptor 131.

The ring 123 can be disposed adjacent a lower liner 140 that is coupled to the chamber body 102. The ring 123 can be disposed around the internal volume of the chamber body 102 and circumscribes the substrate 125 while the substrate 125 is in a processing position. The ring 123 and the susceptor 131 can be formed from a thermally-stable material such as carbon fiber, silicon carbide, quartz or graphite coated with silicon carbide. The ring 123, in combination with the susceptor 131, can separate a processing volume of the upper portion 112. The ring 123 can provide a directed gas flow through the upper portion 112 when the substrate 125 is positioned adjacent to the ring 123.

The support systems 104 include components used to execute and monitor pre-determined processes, such as the growth of epitaxial films and actuation of the substrate support assembly 132 in the processing chamber 100. In one embodiment, the support systems 104 includes one or more of gas panels, gas distribution conduits, power supplies, and process control instruments. The chamber controller 106 is coupled to the support systems 104 and is adapted to control the processing chamber 100 and the support systems 104. In one embodiment, the chamber controller 106 includes a central processing unit (CPU), a memory, and support circuits. Instructions residing in the chamber controller 106 may be executed to control the operation of the processing chamber 100. The processing chamber 100 is adapted to perform one or more film formation or deposition processes therein. For example, a silicon carbide epitaxial growth process may be performed within the processing chamber 100. It is contemplated that other processes may be performed within the processing chamber 100.

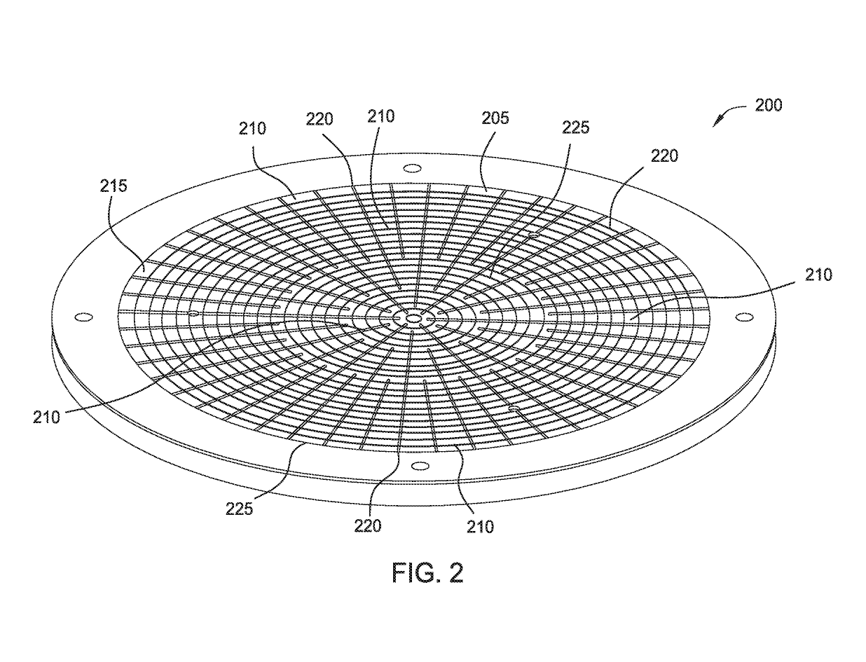

FIG. 2 is a perspective view of one embodiment of a susceptor 200. The susceptor 200 may be used as the susceptor 131 in the processing chamber of FIG. 1. The susceptor 200 includes a substrate receiving surface 205 defined by a plurality of contact structures 210 and a plurality of grooves. Each of the contact structures 210 includes a substrate contact surface 215 and each of the substrate contact surfaces 215 is generally coplanar with every other substrate contact surface 215 across the substrate receiving surface 205. For example, the substrate contact surfaces 215 may include a flatness specification of about 0.1 millimeters (according to geometric dimensioning and tolerancing (GD&T) characteristics) across the substrate receiving surface 205 (e.g., about 300 millimeters (mm)). The flatness tolerance (e.g., about 0.1 mm) references two parallel planes (parallel to the substrate contact surfaces 215) that define a zone where the entire reference surface must lie. The GD&T specification requires the substrate contact surfaces 215 to be within 0.1 mm across the surface area of the substrate receiving surface 205.

The plurality of grooves includes radially oriented grooves 220 and annular grooves 225 that separate each of the plurality of contact structures 210. The annular grooves 225 may be generally concentric in a radial direction. The radially oriented grooves 220 may include different radial lengths. The radially oriented grooves 220 and the annular grooves 225 may intersect across the substrate receiving surface 205.

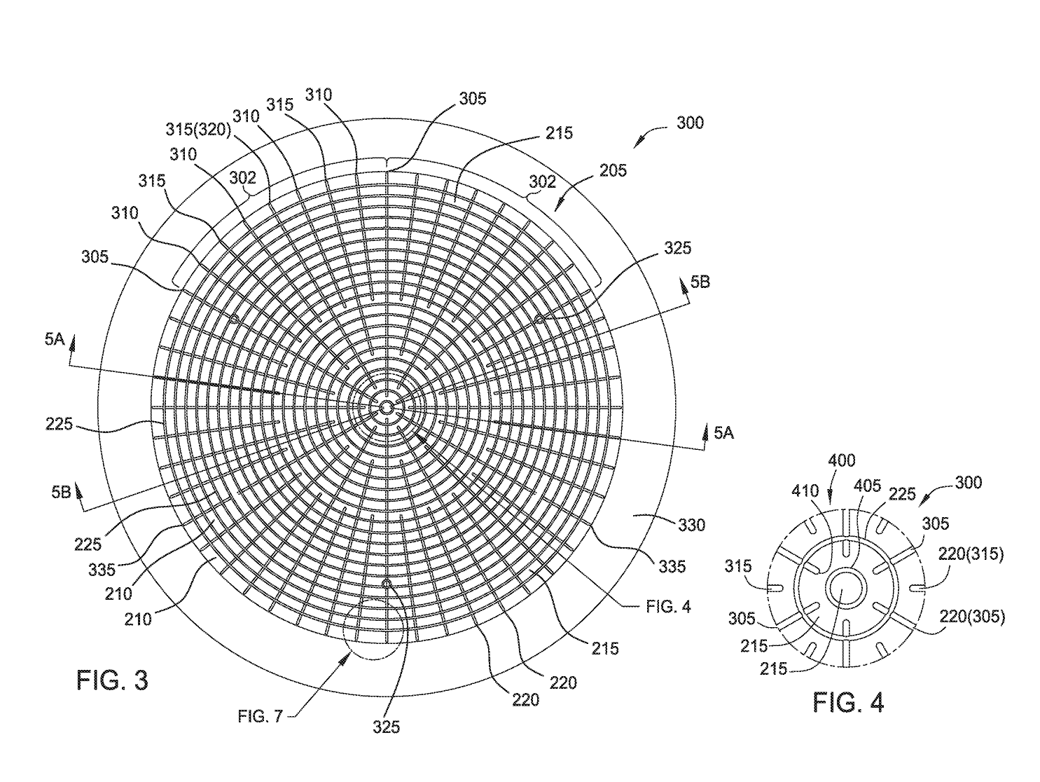

FIG. 3 is a top plan view of another embodiment of a susceptor 300 that may be used as the susceptor 131 in the processing chamber of FIG. 1. The susceptor 300 includes one embodiment of a groove pattern as described below. The susceptor 300 may include the radially oriented grooves 220 having different lengths as a repeating group of grooves 302. The repeating group of grooves 302 are bounded a first groove 305 having a radial length greater than that of other radial grooves of the radially oriented grooves 220 in the repeating group of grooves 302. Immediately adjacent to the first groove 305 is a second groove 310 having a radial length that is less than that of other radial grooves of the radially oriented grooves 220 in the repeating group of grooves 302. Immediately adjacent to the second groove 310 is a third groove 315 having a radial length that is greater than that of the second groove 310 but less than the radial length of the first groove 305. Moving clockwise in FIG. 3, the repeating group of grooves 302 includes other second grooves 310 separated by third grooves 315. One of the third grooves 315 is a central groove 320 that bisects the first grooves 305 and the second grooves 310 within the repeating group of grooves 302. The repeating group of grooves 302 may be disposed at 60 degree intervals on the substrate receiving surface 205. The susceptor 300 also includes openings 325 to receive a lift pin 133 (shown in FIG. 1). The susceptor 300 also includes a peripheral annular surface 330 that in some embodiments may be a portion of the substrate receiving surface 205. However, in other embodiments, the substrate receiving surface 205 is within an area defined by a distal end 335 of the plurality of radially oriented grooves 220. The peripheral annular surface 330 may be coplanar with each of the substrate contact surfaces 215 of the plurality of contact structures 210.

FIG. 4 is an enlarged view of a center area 400 of the susceptor 300 of FIG. 3. The center area 400 includes an annular groove 225 that is intersected by at least a proximal end of the first grooves 305. In this embodiment, a central annular groove 405, disposed radially inward of the annular groove 225, is a complete ring that is not intersected by the radially oriented grooves 220.

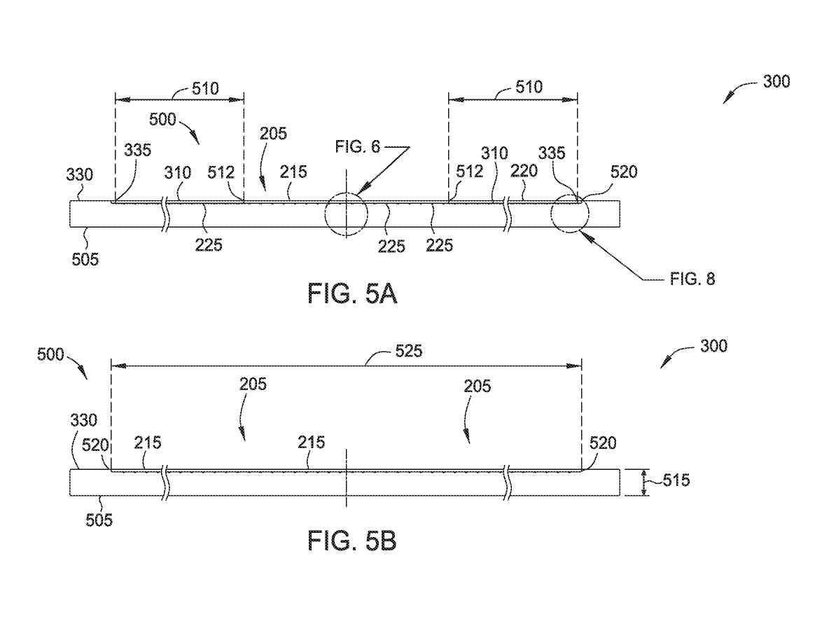

FIGS. 5A and 5B are cross-sectional views of the susceptor 300 along lines 5A-5A, and 5B-5B, of FIG. 3, respectively. In this view, opposing second grooves 310 are shown on the substrate receiving surface 205. The susceptor 300 includes a first major surface 500 and a second major surface 505 opposing the first major surface 500. The first major surface 500 comprises the radially oriented grooves 220, the annular grooves 225 and the substrate contact surfaces 215 as well as the peripheral annular surface 330. The first major surface 500 and the second major surface 505 may be parallel within about 0.1 mm (GD&T characteristic) in some embodiments. A length 510, defined between proximal ends 512 and the distal ends 335 of the second groove 310, may be about 12 mm to about 17 mm, such as about 15 mm. In FIGS. 5A and 5B, a recessed surface 520, where the substrate receiving surface 205 is contained, is shown. The recessed surface 520 may have a length 525 of about 302 mm to about 308 mm. In some embodiments, the susceptor 300 may have a thickness 515 of about 3.5 mm to about 3.9 mm. The susceptor 300 may be made of graphite that may be coated with a ceramic material, such as silicon carbide.

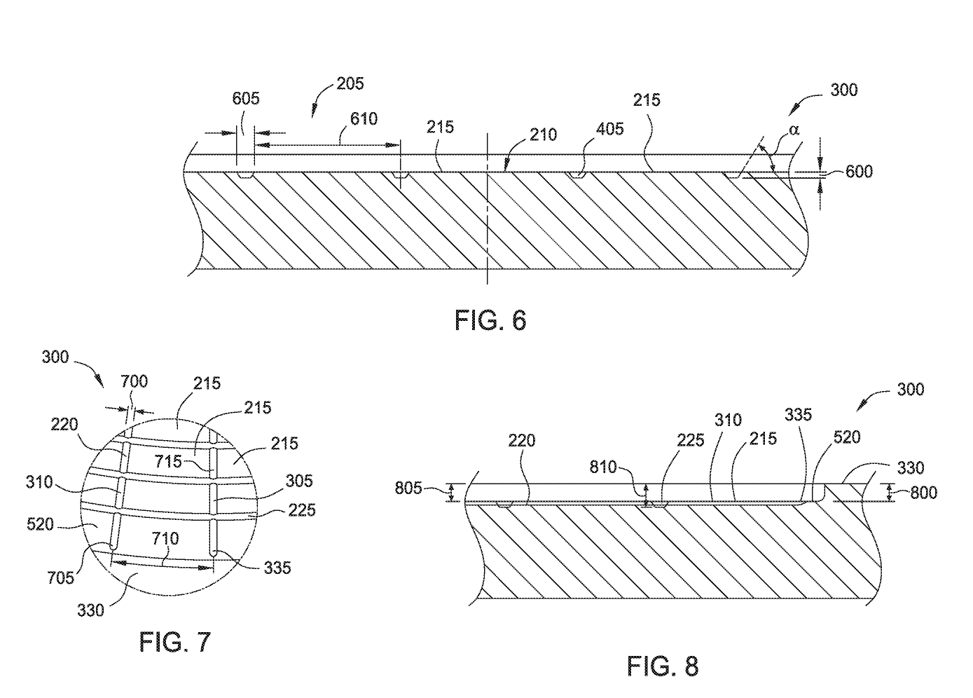

FIG. 6 is an enlarged partial cross-section of the susceptor 300 of FIG. 5A. The geometry of the annular grooves 225 are more clearly shown in this view and include depth 600 of about 0.6 mm to about 0.8 mm. The annular grooves 225 include a maximum width 605 of about 0.65 mm to about 1.0 mm. A pitch 610 between adjacent annular grooves 225 may be about 6 mm to about 7 mm. In some embodiments, each of the annular grooves 225 may include an angle α of about 28 degrees to about 35 degrees.

FIG. 7 is an enlarged partial plan view of the susceptor 300 of FIG. 3. In some embodiments, the radially oriented grooves 220 may include a width 700 of about 0.9 mm to about 1.1 mm. The distal ends 335 of the radially oriented grooves 220 may include a curved end 705. In some embodiments, an angle 710 of about 7 degrees to about 8.5 degrees may be provided between the radially oriented grooves 220. In some embodiments, the radially oriented grooves 220 may comprise a semicircular channel 715 (e.g., half of a circle in cross-section) such that a depth thereof is about half of the width 700. The shape of the radially oriented grooves 220 are thus different than the annular grooves 225 (shown in FIG. 6) according to this embodiment. For example, the radially oriented grooves 220 may be formed with a “ball” type end mill and the annular grooves 225 may be formed with a flat-ended end mill that “flares” to provide the angle α (shown in FIG. 6).

FIG. 8 is an enlarged partial cross-sectional view of the susceptor 300 of FIG. 5A. The recessed surface 520 may be provided at a first depth 800 from the peripheral annular surface 330 and the radially oriented grooves 220 may be provided at a second depth 805 from the peripheral annular surface 330. The first depth 800 may be about 0.9 mm to about 1.05 mm. The second depth 805 may be about 0.8 mm to about 0.9 mm. The annular grooves 225 may be formed to a third depth 810 from the peripheral annular surface 330. The third depth 810 may be about 0.9 mm to about 1.05 mm.

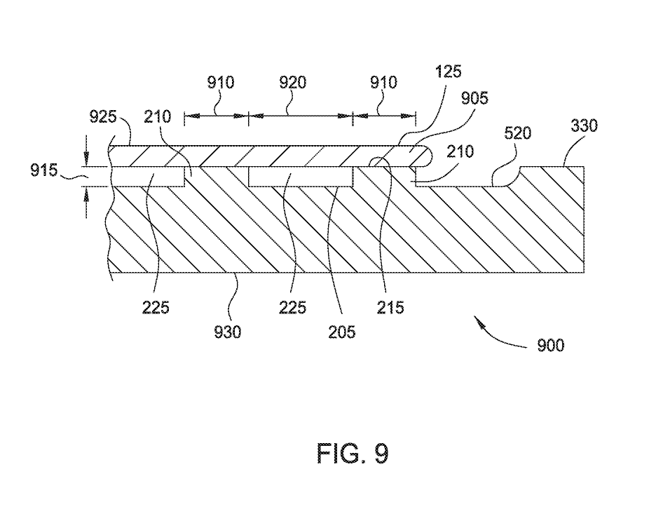

FIG. 9 is a schematic cross-sectional view of a portion of a susceptor 900 that may be used as the susceptor 200 as described herein. The susceptor 900 includes the plurality of contact structures 210 separated by and alternating with the annular grooves 225. Each of the plurality of contact structures 210 have a substrate contact surface 215 that collectively defines a substrate receiving surface 205. A substrate 125 is shown on the substrate contact surfaces 215. In one embodiment, the susceptor 900 is designed such that a peripheral edge 905 of the substrate 125 is in contact with an outer portion of the substrate contact surfaces 215.

In some embodiments, the design parameters of the susceptor 900 include a radial width 910 of the substrate contact surfaces 215, a depth 915 of the annular grooves 225, and a radial width 920 of the annular grooves 225. Many different variations of the design parameters were tested via physical modeling and data regarding substrate temperature as compared to temperature of the susceptor 900 was obtained. More specifically, a radial profile of temperature at an upper surface 925 was compared with a radial profile of temperature at a lower surface 930 of the susceptor 900.

Many different combinations of the design parameters were tested and one objective included minimizing oscillations in the radial profile of temperature at the upper surface 925 of the substrate 125. It was found that some of the design parameters had little to no effect on the radial profile of temperature of the substrate 125. However, the data suggested that the radial width 910 of the substrate contact surfaces 215 may be less than about 1.2 mm, such as about 0.85 mm to about 1 mm, or less. The data also indicated that the depth 915 of the annular grooves 225 may be about 0.12 mm to about 0.5 mm, such as about 0.14 mm to about 0.47 mm. The data also indicated that the radial width 920 of the annular grooves 225 may be about 0.3 mm to about 1.2 mm, such as about 0.4 mm to about 1.1 mm.

Embodiments of the susceptor 200, the susceptor 300 and the susceptor 900 as described herein improve uniformity of the radial temperature profile at the upper surface 925 of the substrate 125. A temperature delta across the radius of a substrate utilizing conventional susceptors may be up to about six degrees Celsius. However, according to the embodiments disclosed herein, the susceptor 200 and the susceptor 900 may reduce the temperature delta such that the temperature delta across the radius of a substrate at an upper surface 925 is at or below 0.2 degrees Celsius. Additionally, using conventional susceptors, a temperature delta from the upper surface 925 of a substrate and the bottom surface of a susceptor may be 30-40 degrees Celsius. According to embodiments disclosed herein, the temperature delta from the upper surface 925 of a substrate and the lower surface 930 of the susceptor 900, or a corresponding surface of the susceptor 200 or 300, may be within about two degrees Celsius, for example about 1 to about 1.5 degrees Celsius. One or both of these temperature delta reductions results in more uniform deposition across the surface of the substrate, and may provide more accurate control of temperature of the substrate during processing. The described embodiments of the susceptor 200, the susceptor 300 and the susceptor 900 may also reduce or eliminate temperature non-uniformities at the edge of the substrate 125 which occurs with conventional susceptors where the substrate edge rests on a ledge. The reduction in the temperature non-uniformity at the edge of the substrate results in increased deposition uniformity.

While the foregoing is directed to embodiments of the present disclosure, other and further embodiments of the disclosure may be devised without departing from the basic scope thereof, and the scope thereof is determined by the claims that follow.

1. A susceptor, comprising:
a first major surface opposing a second major surface; and
a plurality of contact structures disposed on the first major surface, each of the contact structures being at least partially surrounded by one or more of a plurality of radially oriented grooves and an annular groove, wherein each of the plurality of contact structures includes a substrate contact surface, each of the substrate contact surfaces is between two parallel planes separated by a distance of 0.1 millimeters, and the substrate contact surfaces define a substrate receiving surface.

2. The susceptor of claim 1, wherein the substrate receiving surface is within a distal end of the radially oriented grooves.

3. The susceptor of claim 1, wherein the plurality of radially oriented grooves includes a plurality of first grooves each having a first radial length that is less than a radial length of the remainder of the plurality of radially oriented grooves.

4. The susceptor of claim 3, wherein the plurality of radially oriented grooves includes a second groove, and the first grooves are adjacent to, and on both sides of, the second groove.

5. The susceptor of claim 3, wherein the plurality of radially oriented grooves includes a third groove having a second radial length that is greater than the first radial length.

6. The susceptor of claim 1, wherein the plurality of radially oriented grooves comprises a group of grooves across the substrate receiving surface that repeats multiple times.

7. The susceptor of claim 6, wherein the group of grooves includes a first groove having a first radial length that is less than a radial length of the remainder of the radially oriented grooves.

8. The susceptor of claim 7, wherein a second groove is adjacent to, and on both sides of, the first groove.

9. The susceptor of claim 7, wherein the radially oriented grooves include a second groove having a second radial length that is greater than the second radial length.

10. A susceptor, comprising:
a first major surface opposing a second major surface; and
a plurality of contact structures disposed on the first major surface, each of the contact structures being at least partially surrounded by one or more of a plurality of radially oriented grooves and an annular groove, wherein each of the plurality of contact structures includes a substrate contact surface, each of the substrate contact surfaces is coplanar with every other substrate contact surface, the plurality of substrate contact surfaces define a substrate receiving surface, and the plurality of radially oriented grooves includes a first groove having a first radial length and a second groove having second radial length that is less than the remainder of the radially oriented grooves.

11. The susceptor of claim 10, wherein the second groove is adjacent to, and on both sides of, the first groove.

12. The susceptor of claim 10, wherein the radially oriented grooves include a third groove having a third radial length that is less than the first radial length but greater than the second radial length.

13. The susceptor of claim 10, wherein the radially oriented grooves include a third groove having a third radial length that is less than the first radial length but greater than the second radial length.

14. The susceptor of claim 10, wherein the first grooves and second grooves repeat multiple times over the substrate receiving surface.

15. A susceptor, comprising:
a first major surface opposing a second major surface; and
a plurality of contact surfaces disposed on the first major surface, at least a portion of the contact surfaces being separated by, and alternating with, an annular groove, the annular grooves having a width and a depth along a radius of the of the first major surface, wherein each of the plurality of contact surfaces define a substrate receiving surface, and each of the substrate contact surfaces are coplanar with each other within about 0.1 millimeters across the substrate receiving surface.

16. The susceptor of claim 15, further comprising:
a plurality of radially oriented grooves intersecting with the annular grooves.

17. The susceptor of claim 16, wherein the plurality of radially oriented grooves include a first groove having a first radial length that is less than the remainder of the radially oriented grooves.

18. The susceptor of claim 17, wherein a second groove is adjacent to, and on both sides of, the first groove.

19. The susceptor of claim 18, wherein the radially oriented grooves include a third groove having a third radial length that is greater than the first radial length.

20. The susceptor of claim 18, wherein the first grooves and second grooves repeat multiple times over the substrate receiving surface.
